(19) United States
(12) Patent Application Publication
(10) Pub. No.: US 2021/0083222 A1
(43) Pub. Date: Mar. 18, 2021

(54) PACKAGING STRUCTURE FOR OLED DISPLAY

(71) Applicant: Shenzhen China Star Optoelectronics Semiconductor Display Technology Co.,Ltd., Shenzhen (CN)

(72) Inventors: Chunhsiung Fang, Shenzhen (CN); Poyen Lu, Shenzhen (CN)

(73) Assignee: Shenzhen China Star Optoelectronics Semiconductor Display Technology Co.,Ltd., Shenzhen (CN)

(21) Appl. No.: 16/098,866

(22) PCT Filed: Sep. 19, 2018
(86) PCT No.: PCT/CN2018/106578

§ 371 Date: Nov. 5, 2018

(30) Foreign Application Priority Data
May 30, 2018 (CN) 201810542290.0

(51) Int. Cl. H01L 51/52

(52) U.S. Cl. CPC H01L 51/5246; H01L 51/5253

(57) ABSTRACT

The invention provides a packaging structure for OLED display, comprising a glass substrate, a cover glass, a dam sealant, a filling material, and a water-blocking film; the glass substrate and the cover glass being bonded together by the dam sealant coated on peripheral edges of opposite surfaces of the glass substrate and the cover glass, the filling material being filled between the glass substrate and the cover glass on inner side of the dam sealant, and the water-blocking film covering outer surface of the dam sealant. The packaging structure for OLED display of the invention can effectively reduce the dam sealant width while maintaining the same packaging effect, reduce the border width of the display, and enhance the collision resistance of the periphery of the display by spraying a UV light curing adhesive.

### BACKGROUND OF THE INVENTION

### 1. Field of the Invention

The present invention relates to the field of display, and in particular to a packaging structure for organic light-emitting diode (OLED) display.

### 2. The Related Arts

In the panel display technology, the organic light-emitting diode (OLED) display provides many advantages, such as, light and thin, active illumination, fast response speed, large viewing angle, wide color gamut, high brightness and low power consumption, and so on, and has become the third generation display technology after the liquid crystal display (LCD).

The OLED displays can be classified into two categories according to the driving method: passive matrix OLED (PMOLED) and active matrix OLED (AMOLED), namely, direct addressing and thin film transistor (TFT) array addressing, wherein the AMOLED has a plurality of pixels arranged in an array, belongs to an active display type, has high luminous efficiency, and is generally used as a high-definition large-sized display device.

The electroluminescent (EL) materials in OLED displays are very sensitive to water and oxygen in the environment. When water or oxygen invades, the water or oxygen is easy to oxidize with cathode or EL materials, causing damage to EL device or lowering the efficiency. Therefore, it is necessary to use special packaging materials that provide the EL device with good insulation from the environment. Two traditional packaging methods are often used. The first is the dam & fill technology, the other is face seal technology. The dam & fill technology uses a sealant that is highly insulating from the water and oxygen to coat the periphery of the panel to adhere the EL display glass substrate and the packaging cover glass together. A filling material is filled between the display glass substrate and the packaging cover glass to achieve the effect of blocking water and oxygen. Refer to FIG. 1, which is a top view of a conventional AMOLED display, wherein the dam & fill technology is adopted. The glass substrate 1 and the cover glass 2 of the display are bonded together by a dam sealant 3. The dam sealant 3 is applied to the peripheral edges of the opposite surfaces of the glass substrate 1 and the cover glass 2. Referring to FIG. 2, which is a cross-sectional view of a conventional AMOLED display. The glass substrate 1 and the cover glass 2 of the display are bonded together by a dam sealant 3. The dam sealant 3 is applied to the peripheral edges of the opposite surfaces of the glass substrate 1 and the cover glass 2. A filling material 4 is sandwiched between the glass substrate 1 and the cover glass 2. The dam sealant 3 and the filling material 4 form a dam & fill packaging structure to encapsulate the OLED device between the glass substrate 1 and the cover glass 2. The OLED device mainly comprises a passivation film 5, a cathode 6, an electro luminescent material 7, and so on. In general, to achieve better insulation effect, the width D of the dam sealant 3 must be greater than a few millimeters to delay the time of the external environment water and oxygen entering the EL device. The disadvantage is that the packaging method cannot effectively reduce the border width B of the display, wherein the border width B is the width from the effective active area (AA) to the edge of the glass substrate 1.

### SUMMARY OF THE INVENTION

The object of the present invention is to provide a packaging structure for OLED display, able to reduce the width of the dam sealant.

To achieve the above object, the present invention provides a packaging structure for OLED display, which comprises: a glass substrate, a cover glass, a dam sealant, a filling material, and a water-blocking film; the glass substrate and the cover glass being bonded together by the dam sealant coated on peripheral edges of opposite surfaces of the glass substrate and the cover glass, the filling material being filled between the glass substrate and the cover glass on inner side of the dam sealant, and the water-blocking film covering outer surface of the dam sealant.

Wherein, the water-blocking film also extends to cover the peripheral edges of the opposite surfaces of the glass substrate and the cover glass and sides of the glass substrate and the cover glass.

Wherein, the water-blocking film is a film of aluminum oxide or a film of Parylene.

Wherein, the aluminum oxide film is a film prepared by atomic layer deposition (ALD) technology.

Wherein, the aluminum oxide film has a thickness ranging from 50 nm to 200 nm.

Wherein, the Parylene film is a film prepared by a thermal cracking coating technology.

Wherein, the Parylene film has a thickness ranging from 100 nm to 1000 nm.

Wherein, surface of the water-blocking film is disposed with a UV light curing adhesive.

Wherein, the UV light curing adhesive is sprayed on the surface of the water-blocking film by nozzle printing technology.

Wherein, the dam sealant is a UV light curing type material or a thermal curing type material.

In summary, the packaging structure for OLED display of the invention can effectively reduce the dam sealant width while maintaining the same packaging effect, reduce the border width of the display, and enhance the collision resistance of the periphery of the display by spraying a UV light curing adhesive.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a top view showing a known AMOLED display;

FIG. 2 is a cross-sectional view showing a known AMOLED display;

FIG. 3 is a cross-sectional view showing the packaging structure for OLED display of a preferred embodiment of the present invention;

FIG. 4 is a cross-sectional view showing the packaging structure for OLED display of another preferred embodiment of the present invention.

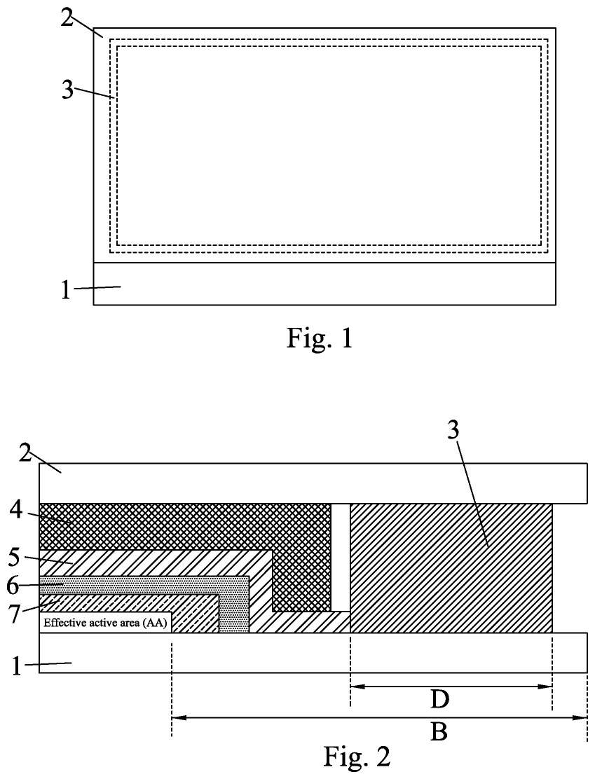

### DETAILED DESCRIPTION OF THE PREFERRED EMBODIMENTS

To further explain the technical means and effect of the present invention, the following refers to embodiments and drawings for detailed description.

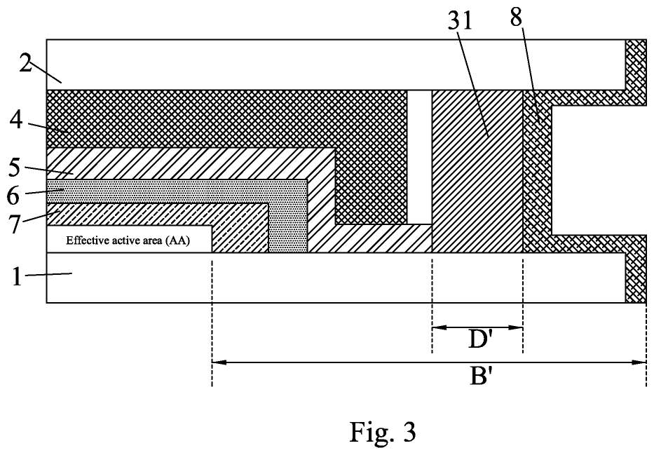

Refer to FIG. 3. FIG. 3 is a cross-sectional view showing the packaging structure for OLED display of a preferred embodiment of the present invention. The packaging structure for OLED display of the present invention comprises: a glass substrate 1, a cover glass 2, a dam sealant 31, a filling material 4, and a water-blocking film 8; the glass substrate 1 and the cover glass 2 are bonded together by the dam sealant 31 coated on peripheral edges of opposite surfaces of the glass substrate 1 and the cover glass 2, the filling material 4 is filled between the glass substrate 1 and the cover glass 2 on inner side of the dam sealant 31, and the water-blocking film 8 covers outer surface of the dam sealant 31. The water-blocking film 8 can further extends to cover the peripheral edges of the opposite surfaces of the glass substrate 1 and the cover glass 2 and sides of the glass substrate 1 and the cover glass 2. The water-blocking film 8 can be a film of aluminum oxide or a film of Parylene. The dam sealant 31 can be a UV light curing type or a thermal curing type material.

The dam sealant 31 and the filling material 4 form a dam & fill packaging structure to encapsulate the OLED device between the glass substrate 1 and the cover glass 2. The OLED device mainly comprises a passivation film 5, a cathode 6, an electro luminescent material 7, and so on.

The present invention is, based on the dam & fill packaging technology, a technology to enhance the packaging around the panel. After the panel is packaged with dam & fill structure, an atomic layer deposition (ALD) technology can be used to coat an Al₂O₃ film around the panel as a water-blocking film 8. The thickest place of the thickest layer of Al₂O₃ film can be about 50 nm-200 nm, because the ALD technology can form a film perfectly matching the shape of the sample, so the water-blocking film 8 can cover the sides of the display glass substrate 1 and the cover glass 2 well, and perfectly cover the side of the dam sealant 31. The Al₂O₃ film grown by the ALD technology provides good water and oxygen barrier properties, so the Al₂O₃ film can effectively reduce the width D′ of the dam sealant 31 and maintain the same packaging effect. Since the width of the dam sealant 31 can be effectively reduced, the border width B′ from the effective active area of the display to the edge of the glass substrate 1 can also be reduced compared to the conventional dam & fill packaging technology.

In addition to the Al₂O₃ film grown using the ALD technology, the present invention can also use a thermal cracking coating technology to grow a Parylene film as a water-blocking film 8. The Parylene film has the same coating property and water and oxygen resistance as the ALD technology and is suitable to replace the Al₂O₃ film. The Parylene film has a thickness ranging about 100 nm-1000 nm.

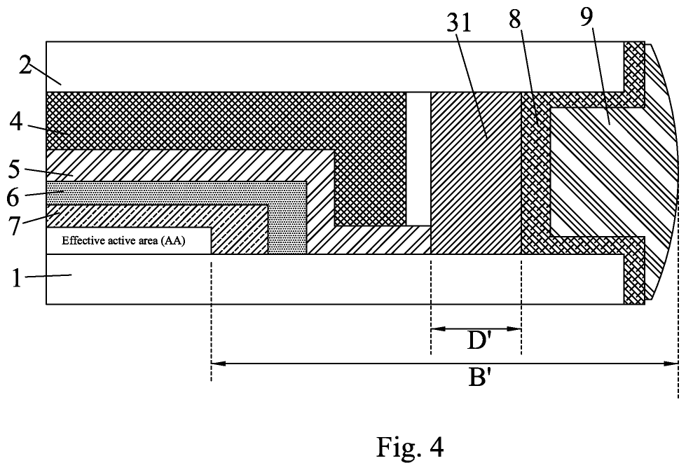

Referring to FIG. 4, FIG. 4 is a cross-sectional view showing the packaging structure for OLED display of another preferred embodiment of the present invention. This preferred embodiment further improves the embodiment in FIG. 3. A UV-curable adhesive 9 is disposed on the surface of the water-blocking film 8. Since the Al₂O₃ or Parylene film as the water-blocking film 8 is thin, the water-blocking film 8 is easily scratched by external hard objects, thereby reducing the ability to block water and oxygen. Therefore, after the Al₂O₃ or Parylene film is formed, a layer of UV light curing adhesive 9 can be sprayed around the periphery by a nozzle printing technology, and the thickness of the UV light curing adhesive 9 is about 0.2 to 0.5 mm, to effectively prevent the risk of scratching Al₂O₃ or Parylene film, and also strengthen the collision resistance at the perimeter of the display. Since the width of the dam sealant 31 can be effectively reduced, the border width B′ of the display can also be reduced compared with the traditional dam & fill packaging structure.

In summary, the packaging structure for OLED display of the present invention can effectively reduce the dam sealant width while maintaining the same packaging effect, reduce the border width of the display, and enhance the collision resistance of the periphery of the display by spraying a UV light curing adhesive.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A packaging structure for organic light-emitting diode (OLED) display, comprising: a glass substrate, a cover glass, a dam sealant, a filling material, and a water-blocking film; the glass substrate and the cover glass being bonded together by the dam sealant coated on peripheral edges of opposite surfaces of the glass substrate and the cover glass, the filling material being filled between the glass substrate and the cover glass on inner side of the dam sealant, and the water-blocking film covering outer surface of the dam sealant.

2. The packaging structure for OLED display as claimed in claim 1, wherein the water-blocking film also extends to cover the peripheral edges of the opposite surfaces of the glass substrate and the cover glass and sides of the glass substrate and the cover glass.

3. The packaging structure for OLED display as claimed in claim 1, wherein the water-blocking film is a film of aluminum oxide or a film of Parylene.

4. The packaging structure for OLED display as claimed in claim 3, wherein the aluminum oxide film is a film prepared by atomic layer deposition (ALD) technology.

5. The packaging structure for OLED display as claimed in claim 3, wherein the aluminum oxide film has a thickness ranging from 50 nm to 200 nm.

6. The packaging structure for OLED display as claimed in claim 3, wherein the Parylene film is a film prepared by a thermal cracking coating technology.

7. The packaging structure for OLED display as claimed in claim 3, wherein the Parylene film has a thickness ranging from 100 nm to 1000 nm.

8. The packaging structure for OLED display as claimed in claim 1, wherein surface of the water-blocking film is disposed with a UV light curing adhesive.

9. The packaging structure for OLED display as claimed in claim 8, wherein the UV light curing adhesive is sprayed on the surface of the water-blocking film by nozzle printing technology.

10. The packaging structure for OLED display as claimed in claim 1, wherein the dam sealant is a UV light curing type material or a thermal curing type material.
